(19) United States
(12) Patent Application Publication
(10) Pub. No.: US 2009/0135322 A1
(43) Pub. Date: May 28, 2009

(54) THIN FILM TRANSISTOR SUBSTRATE, LIQUID CRYSTAL DISPLAY DEVICE HAVING THE SAME AND METHOD OF MANUFACTURING THE SAME

(75) Inventors: Hoon KIM, Asan-si (KR); Seung-Beom PARK, Seoul (KR); Yoon-Sung UM, Yongin-si (KR); Hye-Ran YOU, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD, Suwon-si (KR)

(21) Appl. No.: 12/274,769

(22) Filed: Nov. 20, 2008

(30) Foreign Application Priority Data
Nov. 26, 2007 (KR) 10-2007-0120763

(51) Int. Cl. G02F 1/136; H01L 29/04; H01L 21/84

(52) U.S. Cl. 349/37; 257/59; 438/155; 257/E21.7; 257/E29.003

(57) ABSTRACT

A thin film transistor (“TFT”) substrate includes first through third TFTs, first and second sub pixel electrodes, and a voltage down capacitor. A control terminal and an input terminal of the first and the second TFT are connected to an (N-1)-th gate line and a data line, respectively. The first sub pixel electrode is connected to an output terminal of the first TFT. The second sub pixel electrode is connected to an output terminal of the second TFT. A control terminal and an input terminal of the third TFT are connected to an N-th gate line and the first sub pixel electrode, respectively. The voltage down capacitor is connected to an output terminal of the third TFT. A maximum data voltage transferred from the data line to at least one of the first and second sub pixel electrodes has a range of approximately 14 volts to approximately 16 volts.

This application claims priority to Korean Patent Application No. 10-2007-0120763, filed on Nov. 26, 2007, and all the benefits accruing therefrom under 35 U.S.C. §119, the contents of which in its entirety are herein incorporated by reference.

### BACKGROUND OF THE INVENTION

1. Field of the Invention

The present invention relates to a thin film transistor (“TFT”) substrate and a liquid crystal panel having the TFT substrate. More particularly, the present invention relates to a thin film transistor TFT substrate having improved transmissivity and a liquid crystal panel including the TFT substrate.

2. Description of the Related Art

In general, a liquid crystal panel includes liquid crystal cells arranged in a substantially matrix pattern. A light transmissivity of a liquid crystal display (“LCD”) device is adjusted, based a video signal, by varying an alignment of liquid crystals in the liquid crystal cells, thereby displaying an image on the LCD device. However, a viewing angle of the LCD device is limited, since the image is distorted as a position of a user, e.g., a viewer, changes. Recently, research has been ongoing to develop an LCD having an increased viewing angle to overcome the abovementioned limitation.

In one technique to develop an LCD device having the increased viewing angle, also called a wide-view angle, a vertical alignment (“VA”) mode is used. In the VA mode, liquid crystal molecules having negative permittivity anisotropy are aligned and driven in a vertical direction, based on an electric field direction, to adjust a light transmissivity of the LCD device. In the VA mode, a slit or a protrusion is formed at a common electrode and a pixel electrode of an upper substrate and a lower substrate, and a fringe electric field generated by the slit or the protrusion symmetrically drives the liquid crystal molecules. Thus, the wide-view angle is implemented.

In order to improve a side reproducibility in the VA mode, a pixel electrode formed at one pixel area is divided into a plurality of sub pixel electrodes, and voltages having different gray-scale levels are applied to the sub pixel electrodes to drive the pixel electrode.

To drive the pixel electrode, different driving methods may be utilized. For example, a transistor-transistor (“TT”) method, a capacitor swing (“CS”) method and a capacitor coupling (“CC”) method may be used, but each of the abovementioned driving methods has disadvantages.

In particular, in the TT method, two transistors are used at one gate line and two data lines. More specifically, the two data lines are used at the one pixel area in the TT method, and an opening ratio is thereby reduced, resulting in an increased a data driving cost.

Resistances and capacitances are large in the CS method, and power consumption is therefore increased, relative to alternative driving methods, in the CS method.

In the CC method, a voltage difference between two pixels is small at a low gray-scale level, and reproducibility and transmissivity are therefore decreased in the CC method.

### BRIEF SUMMARY OF THE INVENTION

Exemplary embodiments of the present invention provide a liquid crystal display (“LCD”) device having a simple structure and improved light transmissivity.

Alternative exemplary embodiments of the present invention provide a method of manufacturing the LCD device having the simple structure and improved light transmissivity.

In an exemplary embodiment of the present invention, a thin film transistor (“TFT”) substrate includes a first TFT, a second TFT, a third TFT, a first sub pixel electrode, a second sub pixel electrode and a voltage down capacitor. A control terminal of the first TFT and the second TFT is electrically connected to an (N-1)-th gate line (where N is a natural number), and an input terminal of the first TFT and the second TFT is electrically connected to a data line. The first sub pixel electrode is electrically connected to an output terminal of the first TFT, and the second sub pixel electrode is electrically connected to an output terminal of the second TFT. A control terminal and an input terminal of the third TFT are electrically connected to an N-th gate line and the first sub pixel electrode, respectively, and the voltage down capacitor is electrically connected to an output terminal of the third TFT. A maximum data voltage transferred from the data line to at least one of the first sub pixel electrode and the second sub pixel electrode has a range of approximately 14 V to approximately 16V.

The voltage down capacitor decreases a voltage level charged to the first sub pixel electrode.

In an exemplary embodiment, the first TFT may include a first source electrode, a first drain electrode and a first semiconductor pattern. The first source electrode overlaps at least a first portion of the (N-1)-th gate line, and the first drain electrode is dispose adjacent to the first source electrode and is electrically connected to the first sub pixel electrode. The first semiconductor pattern is disposed between the (N-1)-th gate line and at least one of the first source electrode and the first drain electrode.

The second TFT may include a second source electrode, a second drain electrode and a second semiconductor pattern. The second source electrode overlaps at least a second portion of the (N-1)-th gate line, and the second drain electrode is disposed adjacent to the second source electrode and is electrically connected to the second sub pixel electrode. The second semiconductor pattern is disposed between the (N-1)-th gate line and at least one of the second source electrode and the second drain electrode.

The third TFT may include a third source electrode, a third drain electrode, and a third semiconductor pattern. The third source electrode overlaps at least a third portion the (N-1)-th gate line, and the third drain electrode is disposed adjacent to the third source electrode and is electrically connected to the third sub pixel electrode. The third semiconductor pattern is disposed between the (N-1)-th gate line and at least one of the third source electrode and the third drain electrode.

The TFT substrate may further include an insulation substrate and a storage line disposed on the insulation substrate between the (N-1)-th gate line and the N-th gate line. The voltage down capacitor includes a portion of the storage line, a portion of a gate insulation layer disposed on the storage line, a portion of a third semiconductor pattern and a portion of the third drain electrode.

The maximum data voltage may include a first maximum voltage charged to the first sub pixel electrode, the first maximum voltage charged to the first sub pixel electrode may be approximately 45 percent to approximately 95 percent of a second maximum voltage charged to the second sub pixel electrode.

The voltage down capacitor may decrease a voltage level charged to the first sub pixel electrode.

An area of the second sub pixel electrode may be greater than approximately 1.1 times an area of the first sub pixel electrode.

In an alternative exemplary embodiment, an area of the first sub pixel electrode may be greater than approximately 1.1 times an area of the second sub pixel electrode.

A polarity of a data voltage supplied to at least one of the first sub pixel electrode and the second sub pixel electrode is reversed each consecutive frame.

A shape of at least one of the first pixel electrode and the second sub pixel electrode may be a chevron shape.

In an alternative exemplary embodiment of the present invention, a liquid crystal panel includes a color filter substrate, a TFT substrate and a liquid crystal. The color filter substrate includes a common electrode and a color filter, and the TFT substrate faces, e.g., is disposed opposite to, the color filter substrate. The liquid crystal is vertically aligned between the color filter substrate and the TFT substrate. The TFT substrate includes a first TFT, a second TFT, a third TFT, a first sub pixel electrode, a second sub pixel electrode and a voltage down capacitor. A control terminal of the first TFT and the second TFT is electrically connected to an (N-1)-th gate line (where N is a natural number), and an input terminal of the first TFT and the second TFT is electrically connected to a data line. The first sub pixel electrode is electrically connected to an output terminal of the first TFT, and the second sub pixel electrode is electrically connected to an output terminal of the second TFT. A control terminal and an input terminal of the third TFT are electrically connected to an N-th gate line and the first sub pixel electrode, respectively, and the voltage down capacitor is electrically connected to an output terminal of the third TFT. A maximum data voltage transferred from the data line to at least one of the first sub pixel electrode and the second sub pixel electrode has a range of approximately 14 V to approximately 16V.

The maximum data voltage may include a first maximum voltage charged to the first sub pixel electrode, and the first maximum voltage may be in a range of approximately 45 percent to approximately 95 percent of a second maximum voltage charged to the second sub pixel electrode.

The voltage down capacitor decreases a voltage level charged to the first sub pixel electrode.

The TFT substrate may further include a storage line which supplies a storage voltage to at least one of the first sub pixel electrode and the second sub pixel electrode. The storage line overlaps at least a portion of the first sub pixel electrode and the second sub pixel electrode, and an insulation layer is disposed between the storage line and the at least a portion of the first sub pixel electrode and the second sub pixel electrode to form a first capacitor and a second capacitor. The voltage down capacitor overlaps at least a portion of each of the storage line and a drain electrode of the third TFT, and an insulation layer is disposed between the voltage down capacitor and each of the storage line and the drain electrode of the third TFT.

The common electrode includes a slit which divides a pixel area into a plurality of domains.

At least one of the first sub pixel electrode and the second sub pixel may further include a cutting part.

The storage line is formed to overlap at least a portion of the cutting part.

A polarity of a data voltage supplied to at least one of the first sub pixel electrode and the second sub pixel electrodes is reversed each consecutive frame.

In yet another exemplary embodiment of the present invention, a method of manufacturing a thin film transistor substrate includes: forming an insulation substrate; forming a gate metallic layer on the insulation substrate; etching gate lines, gate electrodes and a storage line from the gate metallic layer using a first mask; forming a gate insulation layer, an amorphous silicon layer and an amorphous silicon layer implanted with impurities on the gate metallic layer; forming a data metallic layer on the amorphous silicon layer implanted with impurities; etching the data metallic layer using a second mask to form a first thin film transistor, a second thin film transistor and a third thin film transistor; forming a protective layer on the data metallic layer using a third mask; forming a first sub pixel electrode and a second sub pixel electrode using a fourth mask; connecting the first thin film transistor and the second thin film transistor to an (N-1)-th gate line (where N is a natural number) and a data line; connecting the first thin film transistor to the first sub pixel electrode; connecting the second thin film transistor to the second sub pixel electrode; connecting the third thin film transistor to an N-th gate line and the first sub pixel electrode; and forming a voltage down capacitor by overlapping the storage line with a drain electrode of the third transistor.

A maximum data voltage transmitted from the data line to at least one of the first sub pixel electrode and the second sub pixel electrode has a range of approximately 14 volts to approximately 16 volts, and the voltage down capacitor decreases a voltage level charged to the first sub pixel electrode.

According to the present invention, a liquid crystal panel applies high a maximum data voltage to one of a first sub pixel electrode and a second sub pixel electrode, and a transmissivity thereof is substantially improved.

In addition, a voltage down capacitor is implemented, thereby simplifying a structure of a pixel area, allowing 120 Hz driving without an additional data line, such that a number of drivers may be reduced. Thus, a manufacturing cost of the liquid crystal panel is effectively reduced.

Further, in an exemplary embodiment of the present invention, a storage capacitor and a voltage down capacitor are formed using only four masks, thereby increasing a production yield of a manufacturing processes thereof.

### BRIEF DESCRIPTION OF THE DRAWINGS

The above and other aspects, features and advantages of the present invention will become more readily apparent by describing in further detail exemplary embodiments thereof with reference to the accompanying drawings, in which:

FIG. 1 is an equivalent schematic circuit diagram of a pixel area of a liquid crystal panel according to an exemplary embodiment of the present invention;

FIGS. 2A to 2B are equivalent schematic circuit diagrams a first sub pixel area according to an exemplary embodiment of the present invention when a gate-on voltage is applied to consecutive associated gate lines;

FIGS. 2C to 2D are equivalent schematic circuit diagrams of a second sub pixel area according to an exemplary embodiment of the present invention when a gate-on voltage is applied to consecutive associated gate lines;

FIG. 3 is a waveform timing diagram showing a charging voltage charged to first pixel area and a second sub pixel area according to the exemplary embodiment of the present invention shown in FIGS. 2A to 2D;

FIG. 4 is a graph of voltage versus brightness illustrating a brightness according to a maximum data voltage supplied to a first sub pixel electrode and a second sub pixel electrode according to an exemplary embodiment of the present invention;

FIG. 5 is a plan view illustrating a pixel of the liquid crystal panel according to the exemplary embodiment of the present invention shown in FIG. 1;

FIG. 6 is a partial cross-sectional view taken along line I-I′ in FIG. 5;

FIG. 7 is a partial cross-sectional view taken along line II-II′ of FIG. 5; and

FIGS. 8A to 11B are partial cross-sectional views illustrating a method of manufacturing a thin film transistor substrate of a liquid crystal panel according to an exemplary embodiment of the present invention.

### DETAIL DESCRIPTION OF THE INVENTION

The invention will now be described more fully hereinafter with reference to the accompanying drawings, in which exemplary embodiments of the invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including,” when used in this specification, specify the presence of stated features, regions, integers, steps, operations, elements and/or components, but do not preclude the presence or addition of one or more other features, regions, integers, steps, operations, elements, components and/or groups thereof.

Furthermore, relative terms, such as “lower” or “bottom” and “upper” or “top” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on the “upper” side of the other elements. The exemplary term “lower” can, therefore, encompass both an orientation of “lower” and “upper,” depending upon the particular orientation of the figure. Similarly, if the device in one of the figures were turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning which is consistent with their meaning in the context of the relevant art and the present disclosure, and will not be interpreted in an idealized or overly formal sense unless expressly so defined herein.

Exemplary embodiments of the present invention are described herein with reference to cross section illustrations which are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes which result, for example, from manufacturing. For example, a region illustrated or described as flat may, typically, have rough and/or nonlinear features. Moreover, sharp angles which are illustrated may be rounded. Thus, the regions illustrated in the figures are schematic in nature and their shapes are not intended to illustrate the precise shape of a region and are not intended to limit the scope of the present invention.

Hereinafter, exemplary embodiments of the present invention will be described in detail with reference to the accompanying drawings.

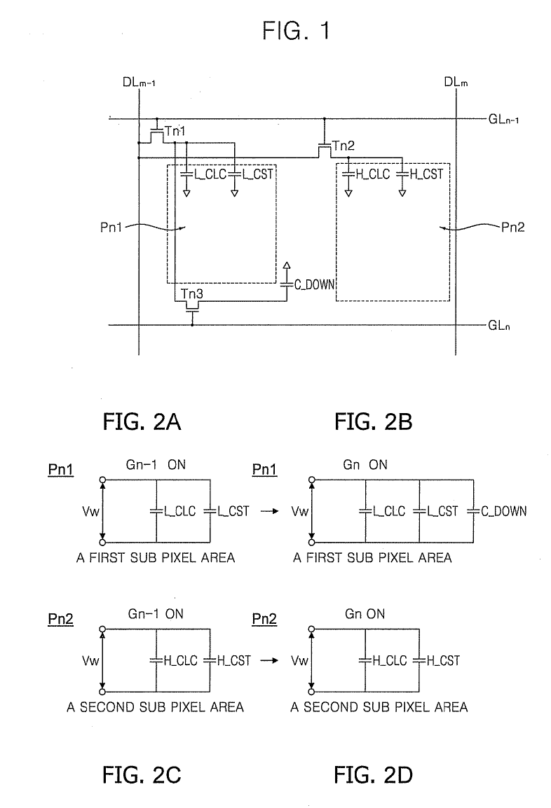

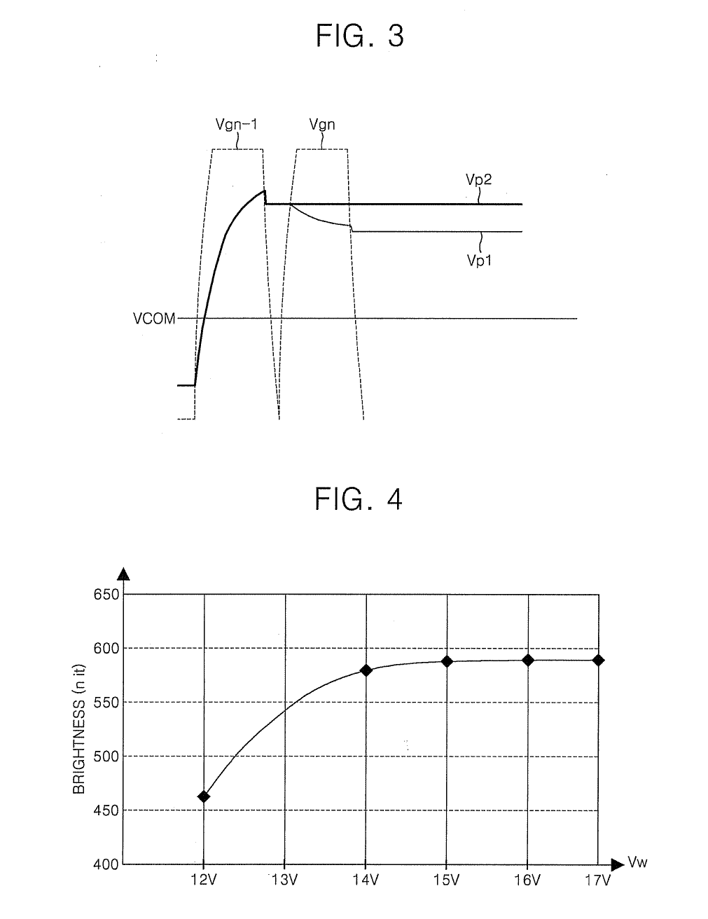

FIG. 1 is an equivalent schematic circuit diagram of a pixel area of a liquid crystal panel according to an exemplary embodiment of the present invention. FIGS. 2A to 2B are equivalent schematic circuit diagrams showing a first sub pixel area according to an exemplary embodiment of the present invention when a gate-on voltage is applied to consecutive associated gate lines. FIGS. 2C to 2D are equivalent schematic circuit diagrams showing a second sub pixel area according to an exemplary embodiment of the present invention when a gate-on voltage is applied to consecutive associated gate lines. FIG. 3 is a waveform timing diagram showing a charging voltage charged to a first sub pixel area and a second sub pixel area according to the exemplary embodiment of the present invention shown in FIGS. 2A to 2D.

Referring to FIGS. 1 to 3, a pixel area includes a first thin film transistor (“TFT”) Tn1 and a second TFT Tn2. The first TFT Tn1 and the second TFT Tn2 are electrically connected to a first sub pixel area Pn1 and a second sub pixel area Pn2, respectively, as well as an (N-1)-th gate line GLₙ₋₁ and an (M-1)-th data line DLₘ₋₁ (where “N” and “M: are natural numbers).

The first sub pixel area Pn1 includes a low voltage liquid crystal capacitor L_CLC and a first storage capacitor L_CST each electrically connected to the first TFT Tn1. The second sub pixel area Pn2 includes a high voltage liquid crystal capacitor H_CLC and a second storage capacitor H_CST each electrically connected to the second TFT Tn2.

The pixel area further includes a third TFT Tn3 and a voltage down capacitor C_DOWN. The third TFT Tn3 is electrically connected to an N-th gate line GLₙ and the voltage down capacitor C_DOWN. In an exemplary embodiment, the voltage down capacitor C_DOWN attenuates a first charging voltage Vp1 (FIG. 3), such that the first charging voltage Vp1 is lower than a second charging voltage Vp2 (FIG. 3). Further, the first charging voltage Vp1 is applied to the first sub pixel area Pn1, and the second charging voltage Vp2 is applied to the second sub pixel area Pn2.

Specifically, the first TFT Tn1 and the second TFT Tn2 are commonly and electrically connected to the (N-1)-th gate line GLₙ₋₁ and the (M-1)-th data line DLₘ₋₁. When a gate-on voltage Vgn-1 is applied to the (N-1)-th gate line GLn-1, the first TFT Tn1 and the second TFT Tn2 are simultaneously turned on and a data voltage (not shown) provided to the (M-1)-th data line DLₘ₋₁ is simultaneously provided to the first sub pixel area Pn1 and the second sub pixel area Pn2. A same amount of data voltages are electrically charged to the first sub pixel area Pn1 and the second sub pixel area Pn2.

When a gate-on voltage Vgn is applied to the N-th gate line GLₙ, a gate-off voltage (not shown) is applied to the (N-1) gate line GLₙ₋₁ and the first charging voltage Vp1 and the second charging voltage Vp2, which are electrically charged to the first sub pixel area Pn1 and the second sub pixel area Pn2, respectively, are attenuated by a kickback effect, and a voltage level of the first charging voltage Vp1 and the second charging voltage Vp2 are thereby lowered. Further, the third TFT Tn3 is turned on and the first charging voltage Vp1 of the first sub pixel area Pn1 shares charges with the voltage down capacitor C_DOWN, and a voltage level thereof is thereby attenuated. When the gate-off voltage is applied to the N-th gate line GLₙ, the third thin film transistor Tn3 is turned off, and the first charging voltage Vp1 charged to the first sub pixel area Pn1 is lowered to a predetermined level by a kickback effect, and the first charging voltage Vp1 is maintained by the low voltage liquid crystal capacitor L_CLC and the first storage capacitor L_CST. In an exemplary embodiment, the gate-off voltage is a common voltage VCOM, but alternative exemplary embodiments are not limited thereto.

Thus, the first charging voltage Vp1 charged to the first sub pixel area Pn1 and the second charging voltage Vp2 charged to the second sub pixel area Pn2 are electrically charged with different values. In addition, including the voltage down capacitor C_DOWN simplifies a structure of the pixel area, and driving the display panel according to an exemplary embodiment of the present invention at 120 Hz is therefore possible without an additional data line, and a manufacturing cost is thereby substantially decreased and/or effectively reduced.

The first charging voltage Vp1 charged to the first sub pixel area Pn1 has a lower voltage level than the second charging voltage Vp2 charged to the second sub pixel area Pn2. In an exemplary embodiment, a voltage ratio of the first charging voltage Vp1 to the second charging voltage Vp2 is increased, thereby improving a transmissivity of the pixel area. More specifically, a voltage level of the second charging voltage Vp2 is raised, and the first charging voltage Vp1 is thereby raised, and the voltage ratio is also thereby raised. Voltages initially charged to the first sub pixel area Pn1 and the second sub pixel area Pn2 are substantially the same, e.g., are substantially equal, and a voltage level of the first charging voltage Vp1 of the first sub pixel area Pn1 is lowered by the voltage down capacitor C_DOWN, and a voltage level charged initially to the first sub pixel area Pn1 is raised. Thus, the voltage level of the first charging voltage Vp1 is raised.

The voltage ratio of the first charging voltage Vp1 to the second charging voltage Vp2 VR is given according to Equation 1.

$$V R = \frac{A charging voltage in a first sub pixel area}{\begin{matrix}A charging voltage in a \\ second sub pixel area\end{matrix} } \qquad < Equation 1 >$$

In an exemplary embodiment, the voltage ratio VR is in a range of approximately 0.045 to approximately 0.95 when a maximum data voltage Vw is applied to the first sub pixel area Pn1 and the second sub pixel area Pn2.

When the voltage ratio VR is less than approximately 0.45, the charging voltage of the first sub pixel area Pn1 is very low, and a transmissivity is thereby decreased. In addition, when the voltage ratio VR is greater than approximately 0.95, an amount of voltage drop by the voltage down capacitor C_DOWN is very small, and reproducibility is not further improved. Thus, the voltage ratio according to an exemplary embodiment is between approximately 0.45 and approximately 0.95, but alternative exemplary embodiments are not limited thereto.

In an exemplary embodiment, the maximum data voltage Vw is in a range of approximately 13 V to approximately 18 V.

FIG. 4 is a graph of voltage versus brightness illustrating a brightness according to a maximum data voltage supplied to a first sub pixel electrode and a second sub pixel electrode according to an exemplary embodiment of the present invention. More specifically, a vertical axis of FIG. 4 represents a measured brightness, and a horizontal axis of FIG. 4 represents a maximum data voltage. Further, FIG. 4 is a graph representing brightness measured when a maximum data voltage Vw corresponding to a 24-inch monitor is varied.

The maximum data voltage Vw applied to the second sub pixel electrode is varied from approximately 12 V to about 17 V in FIG. 4, and a brightness of the 24-inch monitor was measured. As shown in FIG. 4, when the maximum data voltage Vw applied is approximately 12V, brightness of approximately 460 nits results. The maximum data voltage Vw becomes saturated, e.g., increasing the maximum data voltage Vw does not result in a substantial increase in brightness, after approximately 16 V and at approximately 590 nits, as shown in FIG. 4. Thus, in an exemplary embodiment the maximum data voltage Vw is in a range of approximately 14 V to approximately 16 V, but alternative exemplary embodiments are not limited thereto. For example, the maximum data voltage Vw may be below approximately 18 V in a process margin such as a line width or a thickness of a data line generated when a liquid crystal panel is mass-produced. More specifically, when the line width of the data line is narrow and/or the thickness of the data line is thin, a resistance of the data line is increased, and a voltage may be dropped by the resistance, so that the maximum data voltage Vw may be supplied at or below approximately 18 V in an alternative exemplary embodiment.

When the maximum data voltage Vw exceeds approximately 18 V, a gate insulation layer of a crossing part of the data line and the gate line may be damaged. Thus, in an exemplary embodiment the maximum data voltage Vw is less than approximately 18 V.

In an exemplary embodiment, a polarity of the data voltage applied to the first sub pixel electrode Pn1 and the second sub pixel electrode Pn2 is reversed for a given pixel area in consecutive frames. For example, the liquid crystal panel may use a reversion driving method such as a frame reversion, a line reversion, a column reversion, and a dot reversion, but alternative exemplary embodiments are not limited thereto. A polarity of the data voltage for each pixel area may be reversed each frame in the frame reversion, or, alternatively, may be reversed by a line unit in the line reversion, and, likewise, may be reversed by a column unit in the column reversion. A polarity of the data voltage for each pixel area may be reversed by a dot unit in the dot reversion driving method.

In an exemplary embodiment, a voltage difference between the voltage charged in a previous frame and a voltage applied at a current frame is maximized, so that a voltage level charged to the first sub pixel area Pn1 is decreased and a transmissivity may thereby be decreased. The initial voltage level of the first sub pixel area Pn1 and the second sub pixel area Pn2 is a high value, such that a kickback effect by the voltage down capacitor when utilizing the reversion driving method may be effectively reduced.

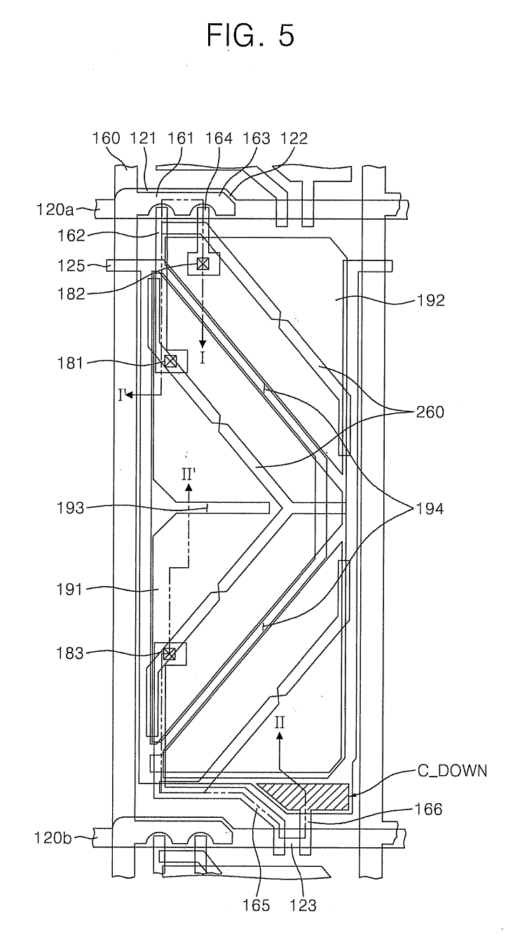

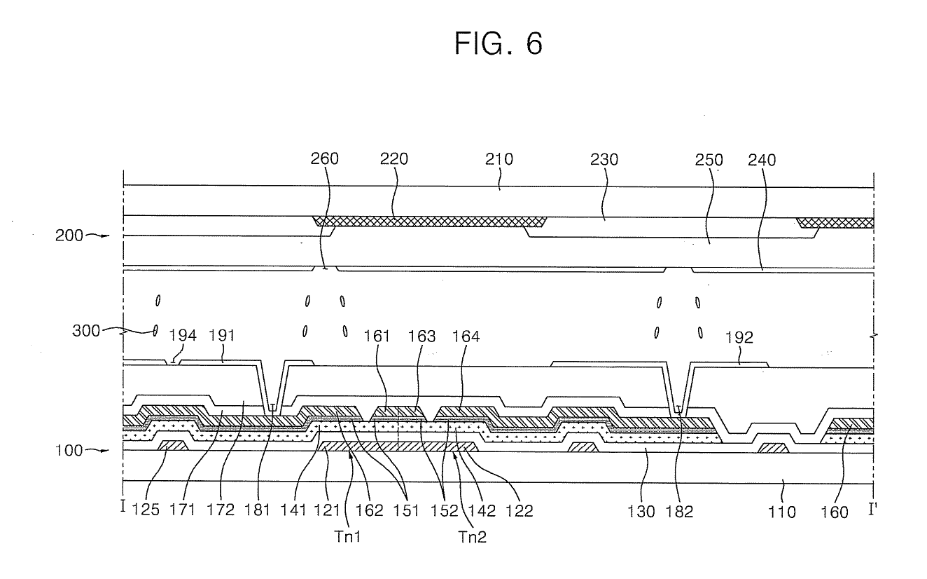

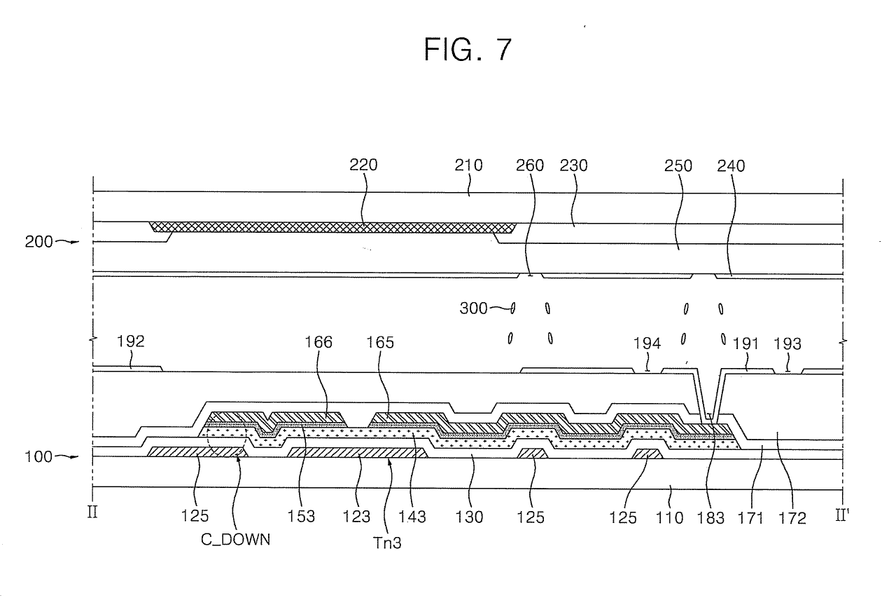

FIG. 5 is a plan view illustrating a pixel of the liquid crystal panel according to the exemplary embodiment of the present invention shown in FIG. 1. FIG. 6 is a partial cross-sectional view taken along line I-I′ of FIG. 5. FIG. 7 is a partial cross-sectional view taken along line II-II′ of FIG. 5.

Referring to FIGS. 5 to 7, a liquid crystal panel according to an exemplary embodiment of the present invention includes a TFT substrate 100, a color filter substrate 200 and a liquid crystal 300.

The liquid crystal 300 is vertically aligned to be driven by a fringe field. The fringe field is formed between the TFT substrate 100 and the color filter substrate 200.

The color filter substrate 200 includes a first insulation substrate 210, a black matrix 220 a color filter 230 and a common electrode 240. The common electrode 240 includes a means for dividing domains, as described in further detail below. The first insulation substrate 210 includes an insulation material such as transparent glass or plastic, for example, but alternative exemplary embodiments are not limited thereto. The black matrix 220 is formed to overlap gate lines 120a and 120b, a data line 160, a first TFT Tn1, a second TFT Tn2, and a third TFT Tn3 of the TFT substrate 100, and, more particularly, the black matrix 220 protects against, e.g., effectively prevents, light leakage from and/or to the abovementioned components. In an exemplary embodiment, the color filter 230 includes color resins such as red, green and blue colors to implement displaying a color image. The common electrode 240 is formed on the color filter 230 and the black matrix 220. In operation, a common voltage VCOM is applied to the common electrode 240, and a liquid crystal capacitor is thereby formed by the common electrode 240, a pixel electrode (described in greater detail below) and the liquid crystal 300 disposed therebetween. In an exemplary embodiment, the common electrode 240 includes a means for dividing domains, e.g., a domain divisional means. The domain divisional means may include a pattern of slits 260 formed in the common electrode 240, as shown in FIG. 5, but alternative exemplary embodiments are not limited thereto. For example, in an alternative exemplary embodiment, a protrusion pattern (not shown) may be used as the domain divisional means.

The common electrode 240 including the slits 260 forms a first sub pixel electrode 191 and a second sub pixel electrode 192, as well as a fringe field formed between each of the first sub pixel electrode 191 and the second sub pixel electrode 192 and the common electrode 240.

The common electrode 240 may further include an overcoat 250 to protect the color filter 230 and the black matrix 220. In an exemplary embodiment, the overcoat 250 is formed between the color filter 230, the black matrix 220 and the common electrode 240, and prevents forming a stepped portion of the color filter 230 proximate to black matrix 220 at the common electrode 240, and distortion of an electric field is thereby effectively prevented in an exemplary embodiment.

The TFT substrate 100 includes a second insulation substrate 110, the gate line 120a and the gate line 120b, the data line 160, the first sub pixel electrode 191, the second sub pixel electrode 192, the TFT Tn1, the second TFT Tn2, the third TFT Tn3, a storage line 125 and a voltage down capacitor C_DOWN.

In an exemplary embodiment of the present invention, the second insulation substrate 110 includes an insulation material such as a transparent glass or plastic, for example.

The gate lines 120a and 120b are disposed in a first direction and are substantially parallel to adjacent gate lines (not shown) on the first substrate 110.

The data line 160 is disposed in a second direction substantially perpendicular to the first direction and is thereby aligned substantially vertically with respect to the gate lines 120a and 120b. The data line 160 is electrically insulated from the gate lines 120a and 120b by a gate insulation layer 130.

The storage line 125 is formed between the gate lines 120a and 120b. In an exemplary embodiment, the storage line 125 does not overlap the gate lines 120a and 120b.

The first TFT Tn1 includes a first gate electrode 121, a first source electrode 161, a first semiconductor layer 141 and a first drain electrode 162. The first semiconductor layer 141 includes a first ohmic contact layer 151 disposed thereon.

The second TFT Tn2 includes a second gate electrode 122, a second semiconductor layer 142, a second source electrode 163 and a second drain electrode 164. A second ohmic contact layer 152 is disposed on the second semiconductor layer 142, as shown in FIG. 6.

The first gate electrode 121 and the second gate electrode 122 may commonly electrically connect to the gate line 120a. The first semiconductor layer 141 and the second semiconductor layer 142 are formed to overlap the first gate electrode 121 and the second gate electrode 122 in an area above the first gate electrode 121 and the second gate electrode 122, respectively.

In an exemplary embodiment of the present invention the first semiconductor layer 141 and the second semiconductor layer 142 include amorphous silicon (“a-Si”) and, in an alternative exemplary embodiment, may include poly silicon (“p-Si”).

The first source electrode 161 and the second source electrode 163 are formed on the first semiconductor layer 141 and the second semiconductor 142 layer to electrically connect to the data line 160. The second source electrode 163 may be formed to connect adjacent to the first source electrode 162. The first source electrode 161 and the second source electrode 163 may be formed to overlap the first gate electrode 121 and the second gate electrode 122, respectively, as shown in FIG. 6.

The first drain electrode 162 is formed opposite to, e.g., facing, the first source electrode 161, and is electrically connected to the first sub pixel electrode 191 through a first contact hole 181. The first drain electrode 162 may be formed on the first semiconductor layer 141. The first ohmic contact layer 151 is formed between the first drain electrode 162 and the first semiconductor layer 141. The first ohmic contact layer 151 may include amorphous silicon implanted with impurities.

The second drain electrode 164 is formed opposite to, e.g., facing, the second source electrode 163, and is electrically connected to the second sub pixel electrode 192 through a second contact hole 182. The second drain electrode 164 may be formed on the second semiconductor layer 142. The second ohmic contact layer 152 is formed between the second drain electrode 164 and the second semiconductor layer 142. The second ohmic contact layer 152 may include amorphous silicon implanted with impurities.

The third TFT Tn3 includes a third gate electrode 123, a third semiconductor layer 143, a third source electrode 165 and a third drain electrode 166.

The third gate electrode 123 is electrically connected to the gate line 120b. In an exemplary embodiment, the third gate electrode 123 may connect to the next gate line 120b directly to prevent deterioration of an opening ratio. The third semiconductor layer 143 includes a third ohmic contact layer 153 disposed thereon. The third semiconductor layer 143 is formed on the gate insulation layer 130 to overlap the third gate electrode 123. The third semiconductor layer 143 may include amorphous silicon or poly silicon.

The third source electrode 165 is formed to overlap the semiconductor layer 143 and the third gate electrode 123. The third source electrode 165 is electrically connected to the first sub pixel electrode 191 through a third contact hole 183.

The third drain electrode 166 is formed opposite to, e.g., facing, the third source electrode 165, and is formed on the third semiconductor layer 143 to overlap the third gate electrode 123. The third drain electrode 166 is also formed to overlap the storage line 125, and thereby forms the voltage down capacitor C_DOWN.

The third ohmic contact layer 153 is formed between the third semiconductor layer 143 and the third source electrode 165, as well as between the third semiconductor layer 143 and the third drain electrode 166. The third ohmic contact layer 153 may include amorphous silicon implanted with impurities.

A protective layer is formed on the gate insulation layer 130, the data line 160, the first source electrode 161, the second source electrode 163, the third source electrode 165, the first drain electrode 162, the second drain electrode 164 and the third drain electrode 166. In an exemplary embodiment, the protective layer includes at least one of an inorganic material and an organic material. Specifically, the protective layer includes an inorganic protective layer 171 and/or an organic protective layer 172, and improves an off characteristic and the opening ratio of the first TFT Tn1, the second TFT Tn2 and the third TFT Tn3.

The first sub pixel electrode 191 is formed on the protective layer, and is electrically connected to the first drain electrode 162 through the first contact hole 181, and is electrically connected to the third source electrode 165 through the third contact hole 183. The first sub pixel electrode 191 is formed to overlap at least a portion of the storage line 125. In an exemplary embodiment of the present invention, the first sub pixel electrode 191 includes a transparent conductive material such as indium tin oxide (“ITO”), indium zinc oxide (“IZO”) or indium tin zinc oxide (“ITZO”), for example, but alternative exemplary embodiments are not limited thereto. Further, the first sub pixel electrode 191 includes a first cutting part 193 for dividing the domains, as described in greater detail above.

Specifically, in an exemplary embodiment, the first cutting part 193 divides the first sub pixel electrode 191 into a plurality of domains and, more specifically, divides the first sub pixel electrode 191 into the plurality of domains by partially cutting a portion of the first sub pixel electrode 191 along a vertical axis thereof, as shown in FIG. 5. In an exemplary embodiment, the first cutting part 193 does not cut the first sub pixel electrode 191 completely into separate parts. The first cutting part 193 is formed longitudinally from a first end portion to an opposite second end portion of the first sub pixel electrode 191, as shown in FIG. 5.

The second sub pixel electrode 192 is formed on the organic protective layer 172, and is electrically connected to the second drain electrode 164 through the second contact hole 182. The second sub pixel electrode 192 overlaps at least a portion of the storage line 125. In an exemplary embodiment, the second sub pixel electrode 192 includes a transparent conductive material such ITO, IZO and/or ITZO, for example, but alternative exemplary embodiments are not limited thereto. In an exemplary embodiment, the transparent conductive material of the second sub pixel 192 is substantially the same as the transparent conductive material of the first sub pixel electrode 191.

The first sub pixel electrode 191 and the second sub pixel electrode 192 are divided by a second cutting part 194, which divides areas of the first sub pixel electrode 191 and the second sub pixel electrode 192 into a plurality of domains. The second cutting part 194 overlaps the storage line 125 to effectively prevent light leakage from and/or into the second cutting part 194.

As illustrated in FIG. 5, the first sub pixel electrode 191 and the second sub pixel electrode 192, may be formed in a substantially chevron shape, but alternative exemplary embodiments are not limited thereto. For example, the first sub pixel electrode 191 and the second sub pixel electrode 192 may be formed in different shapes than as shown in FIG. 5. Specifically, the first sub pixel electrode 191 and the second sub pixel electrode 192 may be formed to have a substantially zigzag shape or “V” shapes, but alternative exemplary embodiments of the present invention are not limited thereto.

In an exemplary embodiment, the voltage down capacitor C_DOWN is formed by overlapping the storage line 125 with the third drain electrode 166 between the gate insulation layers 130. However, the voltage down capacitor C_DOWN may be formed by overlapping the storage line 15 with the third drain electrode 166 between the gate insulation layer 130, the third semiconductor layer 143 and the third ohmic contact layer 153 in an alternative exemplary embodiment.

In an exemplary embodiment, the first storage capacitor L_CST (see FIGS. 1 and 2A-2B) is formed by overlapping the first sub pixel electrode 191 and a portion of the storage line 125 between the gate insulation layer 130, the inorganic protective layer 171 and the organic protective layer 172. Likewise, he second storage capacitor H_CST (FIGS. 1 and 2C-2D) is formed by overlapping the second sub pixel electrode 192 with a portion of the storage line 125 between the gate insulation layer 130, the inorganic organic protective layer 171 and the organic protective layer 172.

In an exemplary embodiment, the liquid crystal panel the second sub pixel electrode 192 includes at least approximately 1.1 times greater area than an area of the first sub pixel electrode 191, as shown in FIG. 5. Thus, the second sub pixel electrode 192 has a higher voltage than the first sub pixel electrode 191, due to the second sub pixel electrode 192 having a greater area than the area of first sub pixel electrode 191, and a transmissivity of the liquid crystal panel according to an exemplary embodiment is thereby substantially improved. In an exemplary embodiment of the present invention, a brightness of a pixel area is greater than approximately 15% to approximately 60% of a maximum brightness of the pixel area.

In an alternative exemplary embodiment, however, when the brightness of the pixel area is less than approximately 15% to approximately 60% of the maximum brightness of the pixel area, the area of the first sub pixel electrode 191 is greater than approximately 1.1 times of the area of the second sub pixel electrode 192.

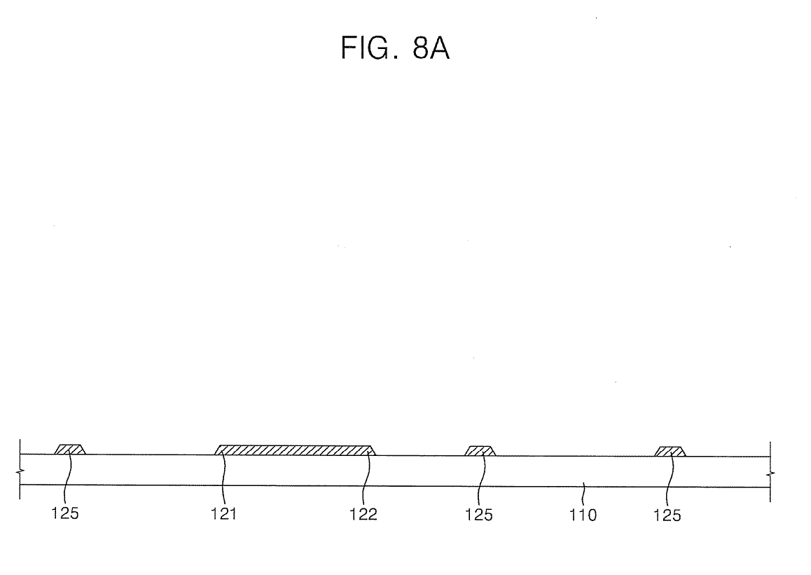

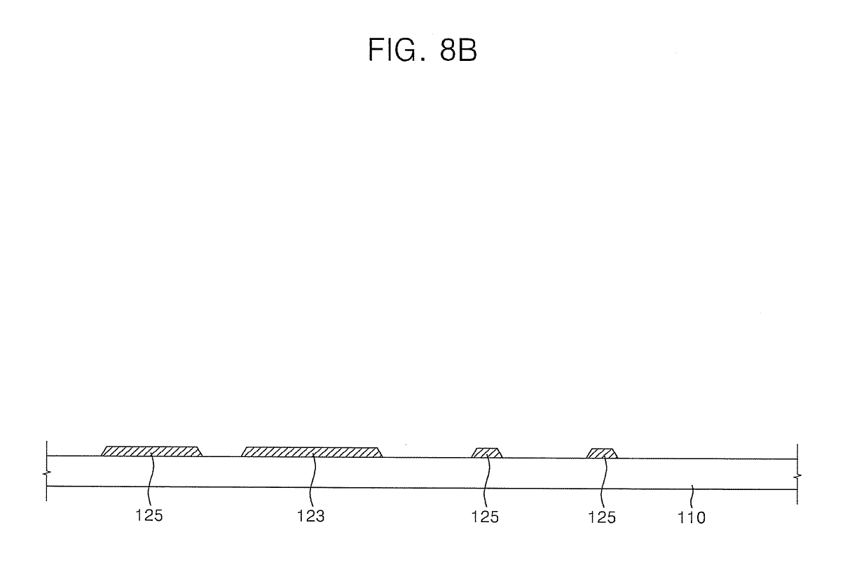

FIGS. 8A to 11B are partial cross-sectional views illustrating a method of manufacturing a thin film transistor substrate of a liquid crystal panel according to an exemplary embodiment of the present invention. The same reference characters in FIGS. 8A to 11B denote the same or like components as in FIGS. 1 to 7, and any repetitive detailed description thereof will hereinafter be omitted.

Referring to FIGS. 8A and 8B, a gate pattern (not fully shown) including a gate line, a first gate electrode 121, a second gate electrode 122, a third gate electrode 123 and a storage line 125 is formed by a first mask process.

More specifically, a gate metallic layer is formed by a sputtering method, for example, on an insulation substrate 110. The gate metallic layer may include a single metal, or alloy thereof, including molybdenum (Mo), aluminum (Al), chrome (Cr) and copper (Cu), for example, but not being limited thereto. The gate metallic is formed as a single layer, or, in an alternative exemplary embodiment, may be formed of multiple, e.g., two or more, layers.

Thus, the gate metallic layer is patterned by a photolithography process and an etching process, for example, using a first mask to form a gate pattern including the first gate electrode 121, the second gate electrode 122, the third gate electrode 123 and the storage line 125.

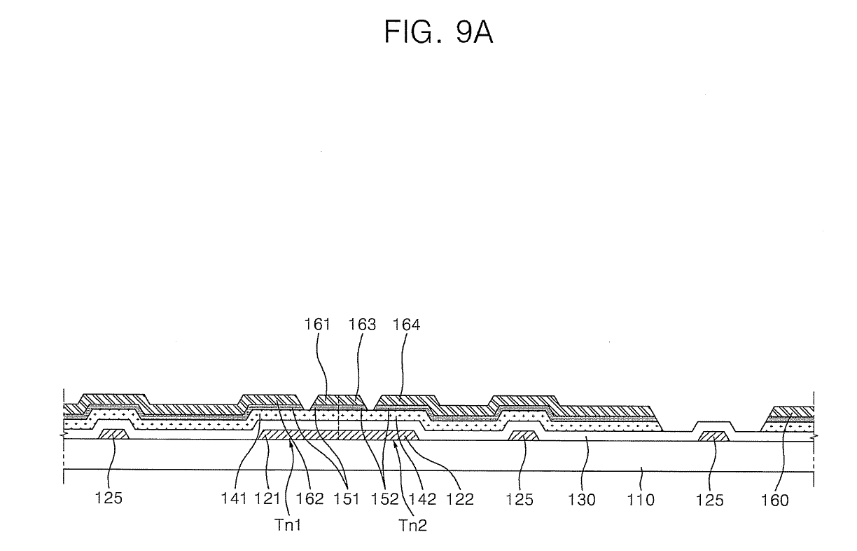

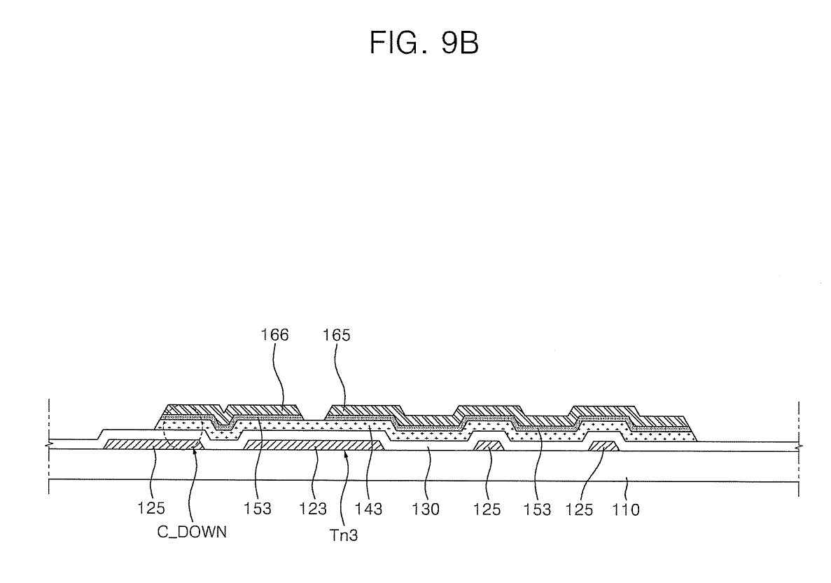

Referring to FIGS. 9A and 9B, a gate insulation layer 130, an amorphous silicon layer and an amorphous silicon layer implanted with impurities are sequentially laminated on the patterned gate metallic layer (FIGS. 8A and 8B) by a method such as plasma enhanced chemical vapor deposition (“PECVD”) and/or chemical vapor deposition (“CVD”), for example, but not being limited thereto. Next, a data metallic layer (not fully shown) is formed on the amorphous silicon layer implanted with impurities by a sputtering method, for example.

The gate insulation layer 130 may include silicon nitride (“SiNx”) or silicon oxide (“SiOx”). The data metallic layer may include a single metal, or an alloy thereof, including, but not limited to, molybdenum (Mo), aluminum (Al), chrome (Cr) and copper (Cu). The data metallic layer may be formed as a single layer or, alternatively, as a multiple layer including two or more single layers.

Photo-resist is coated on the abovementioned components, and a stepped photo-resist pattern is formed by a photo-lithography process, for example, using a second mask (not shown). Portions of the photo-resist pattern remain proximate to areas which correspond to locations in which channels of the first to the third TFTs will be formed. The photo-resist pattern remains in areas in which the data pattern will be formed, and the photo-resist pattern is removed completely from remaining areas.

Next, a second etching process is performed, wherein the data metallic layer of the pixel area is formed, and the amorphous silicon layer implanted with impurities and the amorphous silicon layer are then etched by a second etching process. The photo-resist is removed by an ashing process, for example. The amorphous silicon layer implanted with impurities is removed by a third etching process, and the remaining photo-resist is removed to form a data pattern including a data line 160, a first source electrode 161, a second source electrode 163, a third source electrode 165, a first drain electrode 162, a second drain electrode 164 and a third drain electrode 166. A first semiconductor layer 141, a second semiconductor layer 142, a third semiconductor layer 143, a first ohmic contact layer 151, a second ohmic contact layer 152 and a third ohmic contact layer 153 are then formed under the data pattern.

The third drain electrode 166 is formed to overlap at least a portion of the storage line 125 to form a voltage down capacitor C_DOWN. Alternatively, the storage line 125 and the third drain electrode 166 overlap each other between portions of the gate insulation layer 130, the third semiconductor layer 143 and the third ohmic contact layer 153, thereby forming the voltage down capacitor C_DOWN.

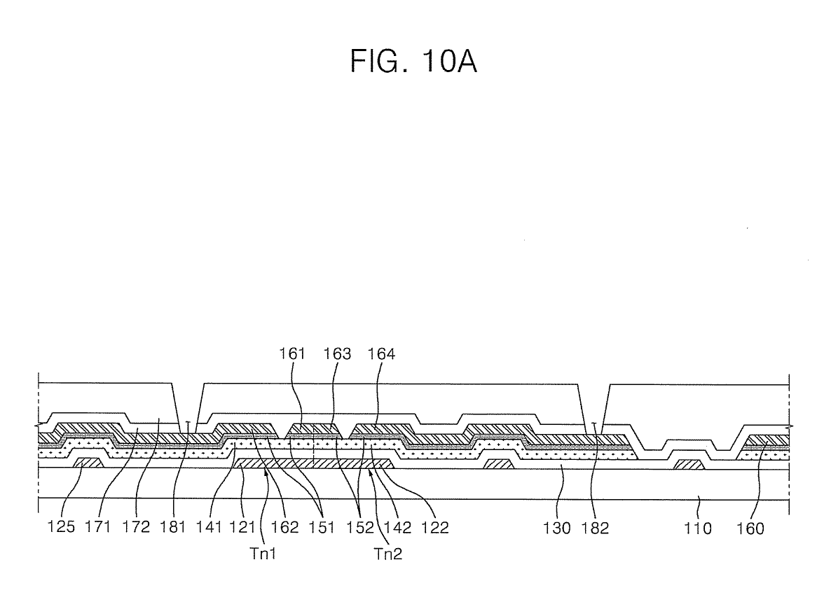

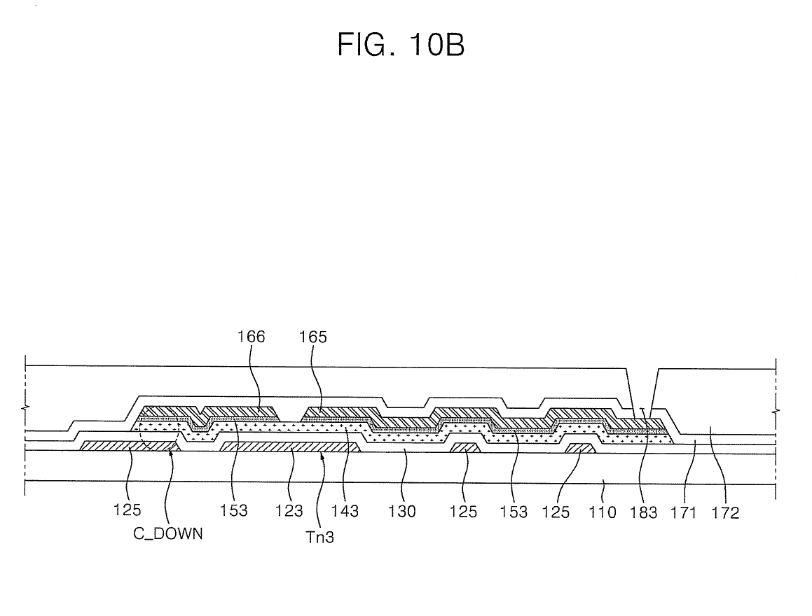

Referring to FIGS. 10A and 10B, a protective layer having a first contact hole 161, a second contact hole 162 and a third contact hole 163 is formed by a third mask process.

Specifically, at least one of an organic material and inorganic material is formed on the insulation substrate 110 having the data pattern by a deposition method such as the PECVD and/or CVD, for example. The protective layer having the first contact hole 161, the second contact hole 162 and the third contact hole 163 by a photo-lithography process and an etching using the third mask. The protective layer may be formed by laminating an inorganic protective layer 171 and an organic protective layer 172, as illustrated in FIGS. 10A and 10B.

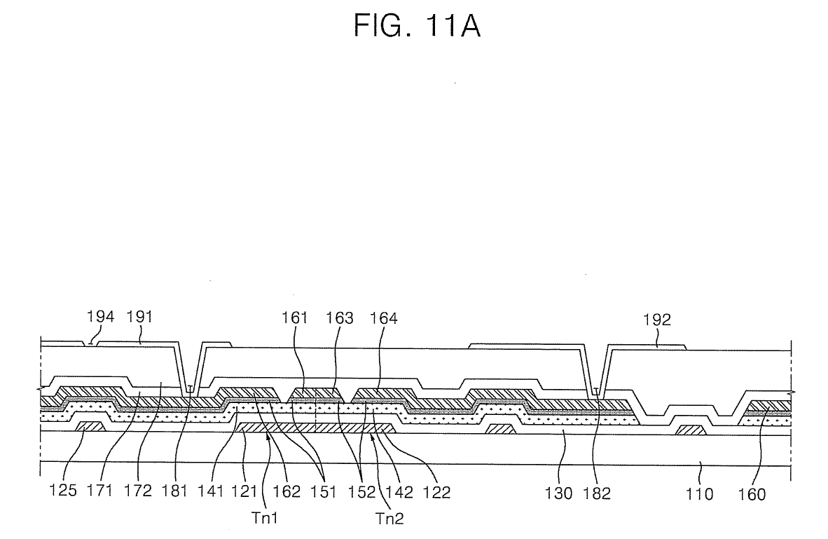

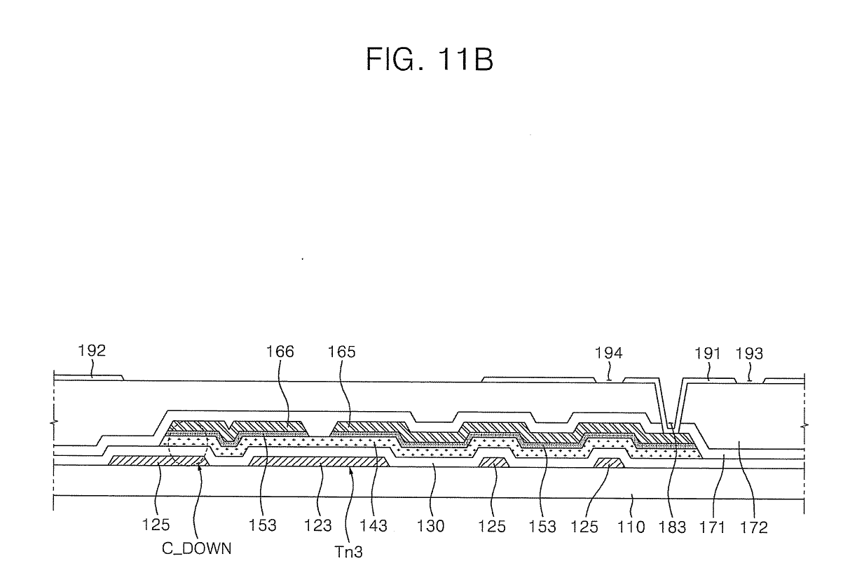

Referring to FIGS. 11A and 11B, a pixel electrode pattern including a first sub pixel electrode 191 and a second sub pixel electrode 192 are formed by a fourth mask process.

More specifically, a transparent conductive material such as ITO, IZO and/or ITZO, for example, is formed on the organic protective layer 172 by a deposition method such as the sputtering method. The first sub pixel electrode 191 and the second sub pixel electrode 192 are then patterned by a photo-lithography process and an etching process using a fourth mask. The first sub pixel electrode 191 and the second sub pixel electrode 192 are formed to be divided by a second cutting part 194. The first sub pixel electrode 191 is formed to overlap with the storage line 125 to form the first storage capacitor L_CST (see FIGS. 1 and 2A-2B). The second sub pixel electrode 192 is formed to overlap the storage line 125 to form the second storage capacitor H_CST (FIGS. 1 and 2C-2D).

The first sub pixel electrode 191 is formed to further include a first cutting part 193.

According to exemplary embodiments of the present invention as described herein, a voltage down capacitor, a first storage capacitor and a second storage capacitor are sequentially formed by a four mask process, and a manufacturing process is thereby effectively simplified. Further, an organic protective layer may be formed in an alternative exemplary embodiment.

The present invention should not be construed as being limited to the exemplary embodiments set forth herein. Rather, these exemplary embodiments are provided so that this disclosure will be thorough and complete and will fully convey the concept of the present invention to those skilled in the art.

While the present invention has been particularly shown and described with reference to exemplary embodiments thereof, it will be understood by those of ordinary skill in the art that various changes in form and details may be made therein without departing from the spirit or scope of the present invention as defined by the following claims.

What is claimed is:

1. A thin film transistor substrate comprising:
a first thin film transistor and a second thin film transistor, each transistor electrically connected to an (N-1)-th gate line (where N is a natural number) and a data line;
a first sub pixel electrode electrically connected to the first thin film transistor;
a second sub pixel electrode electrically connected to the second thin film transistor;
a third thin film transistor electrically connected to an N-th gate line and the first sub pixel electrode; and
a voltage down capacitor electrically connected to the third thin film transistor,
wherein a maximum data voltage transferred from the data line to at least one of the first sub pixel electrode and the second sub pixel electrode has a range of approximately 14 volts to approximately 16 volts.

2. The thin film transistor substrate of claim 1, wherein the voltage down capacitor decreases a voltage level charged to the first sub pixel electrode.

3. The thin film transistor substrate of claim 1, wherein
the first thin film transistor comprises:
a first source electrode which overlaps at least a first portion of the (N-1)-th gate line;
a first drain electrode disposed adjacent to the first source electrode and electrically connected to the first sub pixel electrode; and
a first semiconductor pattern disposed between the (N-1)-th gate line and at least one of the first source electrode and the first drain electrode,
the second thin film transistor comprises:
a second source electrode which overlaps at least a second portion of the (N-1)-th gate line;
a second drain electrode disposed adjacent to the second source electrode and electrically connected to the second sub pixel electrode; and
a second semiconductor pattern disposed between the (N-1)-th gate line and at least one of the second source electrode and the second drain electrode, and
the third thin film transistor comprises:
a third source electrode which overlaps at least a third portion of the (N-1)-th gate line;
a third drain electrode disposed adjacent to the third source electrode and electrically connected to the third sub pixel electrode; and
a third semiconductor pattern disposed between the (N-1)-th gate line and at lest one of the third source electrode and the third drain electrode.

4. The thin film transistor substrate of claim 3, further comprising:
an insulation substrate; and
a storage line disposed on the insulation substrate between the (N-1)-th gate line and the N-th gate line, wherein
the voltage down capacitor comprises a portion of the storage line, a portion of a gate insulation layer disposed on the storage line, a portion of a third semiconductor pattern disposed on the gate insulation layer and a portion of the third drain electrode.

5. The thin film transistor substrate of claim 4, wherein
the maximum data voltage comprises a first maximum voltage charged to the first sub pixel electrode, and
the first maximum voltage has a range of approximately 45 percent to approximately 95 percent of a second maximum voltage charged to the second sub pixel electrode.

6. The thin film transistor substrate of claim 5, wherein the voltage down capacitor decreases a voltage level charged to the first sub pixel electrode.

7. The thin film transistor substrate of claim 6, wherein an area of the second sub pixel electrode is greater than approximately 1.1 times an area of the first sub pixel electrode.

8. The thin film transistor substrate of claim 6, wherein an area of the first sub pixel electrode is greater than approximately 1.1 times an area of the second sub pixel electrode.

9. The thin film transistor substrate of claim 1, wherein a polarity of a data voltage supplied to at least one of the first sub pixel electrode and the second sub pixel electrode is reversed each consecutive frame.

10. The thin film transistor substrate of claim 1, wherein a shape of at least one of the first pixel electrode and the second sub pixel electrode comprises a chevron shape.

11. A liquid crystal panel comprising:
a color filter substrate comprising a common electrode and a color filter disposed on the common electrode;
a thin film transistor substrate disposed opposite to the color filter substrate; and
a vertically aligned liquid crystal layer disposed between the color filter substrate and the thin film transistor substrate,
wherein the thin film transistor substrate comprises:
a first thin film transistor and a second thin film transistor, each transistors electrically connected to an (N-1)-th gate line (where N is a natural number) and a data line;
a first sub pixel electrode electrically connected to the first thin film transistor;
a second sub pixel electrode electrically connected to the second thin film transistor;
a third thin film transistor electrically connected to an N-th gate line and the first sub pixel electrode; and
a voltage down capacitor electrically connected to the third thin film transistor,
wherein a maximum data voltage transferred from the data line to at least one of the first sub pixel electrode and the second sub pixel electrode has a range of approximately 14 volts to approximately 16 volts.

12. The liquid crystal panel of claim 11, wherein
the maximum data voltage comprises a first maximum voltage charged to the first sub pixel electrode, and
the first maximum voltage has a range of approximately 45 percent to approximately 95 percent of a second maximum voltage charged to the second sub pixel electrode.

13. The liquid crystal panel of claim 12, wherein the voltage down capacitor decreases a voltage level charged to the first sub pixel electrode.

14. The liquid crystal panel of claim 12, wherein
the thin film transistor substrate further comprises a storage line which supplies a storage voltage to at least one of the first sub pixel electrode and the second sub pixel electrode,
the storage line overlaps at least a portion of the first sub pixel electrode and the second sub pixel electrode,
an insulation layer is disposed between the storage line and the at least a portion of the first sub pixel electrode and the second sub pixel electrode to form a first capacitor and a second capacitor,
the voltage down capacitor overlaps at least a portion of each of the storage line and a drain electrode of the third thin film transistor, and
an insulation layer is disposed between the voltage down capacitor and each of the storage line and the drain electrode of the third thin film transistor.

15. The liquid crystal panel of claim 14, wherein the common electrode comprises a slit which divides a pixel area into a plurality of domains.

16. The liquid crystal panel of claim 15, wherein at least one of the first sub pixel electrode and the second sub pixel electrode further comprises a cutting part.

17. The liquid crystal panel of claim 16, wherein the storage line overlaps at least a portion of the cutting part.

18. The liquid crystal panel of claim 11, wherein a polarity of a data voltage supplied to at least one of the first sub pixel electrode and the second sub pixel electrodes is reversed each consecutive frame.

19. A method of manufacturing a thin film transistor substrate, the method comprising:
forming an insulation substrate;
forming a gate metallic layer on the insulation substrate;
etching gate lines, gate electrodes and a storage line from the gate metallic layer using a first mask;
forming a gate insulation layer, an amorphous silicon layer and an amorphous silicon layer implanted with impurities on the gate metallic layer;
forming a data metallic layer on the amorphous silicon layer implanted with impurities;
etching the data metallic layer using a second mask to form a first thin film transistor, a second thin film transistor and a third thin film transistor;
forming a protective layer on the data metallic layer using a third mask;
forming a first sub pixel electrode and a second sub pixel electrode using a fourth mask;
connecting the first thin film transistor and the second thin film transistor to an (N-1)-th gate line (where N is a natural number) and a data line;
connecting the first thin film transistor to the first sub pixel electrode;
connecting the second thin film transistor to the second sub pixel electrode;
connecting the third thin film transistor to an N-th gate line and the first sub pixel electrode; and
forming a voltage down capacitor by overlapping the storage line with a drain electrode of the third transistor;
wherein a maximum data voltage transmitted from the data line to at least one of the first sub pixel electrode and the second sub pixel electrode has a range of approximately 14 volts to approximately 16 volts.

20. The method of claim 19, wherein the voltage down capacitor decreases a voltage level charged to the first sub pixel electrode.
